(19) United States
(12) Patent Application Publication
(10) Pub. No.: US 2026/0349027 A1
(43) Pub. Date: Nov. 5, 2026

(54) Device and Method for Testing Semiconductor Wafers

(71) Applicant: ERS Electronic GmbH, Germering (DE)

(72) Inventor: Klemens Reitinger, Germering (DE)

(21) Appl. No.: 19/484,699

(22) PCT Filed: Feb. 20, 2024
(86) PCT No.: PCT/EP2024/054294

§ 371 Date: Nov. 14, 2025

(30) Foreign Application Priority Data
Jun. 2, 2023 (DE) 10 2023 114 565.7

(51) Int. Cl. G01R 31/28

(52) U.S. Cl. CPC G01R 31/2877; G01R 31/2865; G01R 31/2875

(57) ABSTRACT

A device and a method is provided for testing semiconductor wafers using a temperature-controllable clamping device. The device is equipped with a temperature-controllable clamping device having a chuck device and a plate-shaped zone heating device which can be applied to the chuck device and has a plurality of discrete heating zones the heating zones being arranged in the form of a planar matrix below a support face of the zone heating device and each being enclosed by a lateral thermal insulation region a test control device for testing a temperature-controlled semiconductor wafer clamped on the support face of the zone heating device by imposing a predetermined electric test power on each chip to be tested, on the front face of the semiconductor wafer via probes of a probe card a temperature control device which is connected to the test device the chuck device and the zone heating device and set up, for the purpose of setting a predetermined measurement temperature, to control the chuck device to a predetermined cooling power using a coolant fluid and to control an associated heating zone corresponding to the chip to be tested to a predetermined heating power the predetermined heating power being greater than the predetermined test power a temperature detection device for detecting a temperature increase during testing and passing the temperature increase to the temperature control device the temperature control device being set up to reduce the heating power at a constant cooling power on the basis of the directly detected chip temperature increase during testing, so as to stabilise the measurement temperature.

The present invention relates to a device and a method for testing semiconductor wafers using a temperature-controllable clamping device.

The present invention and the set of problems underlying it are explained herein by way of integrated circuits on the wafer plane, but are not limited thereto.

In the manufacturing sequence for the production of integrated circuits, wafer tests are carried out on wafers which have not yet been split, so as be able to detect faulty integrated circuits early and separate them out. For this purpose, a wafer to be tested is inserted into a wafer prober and brought to a desired testing temperature by means of a temperature-controllable chuck (device for temperature-controlling the wafer substrate) located therein. When the wafer is at the desired test temperature, an electrical connection to the contact areas of the integrated circuit to be tested is established using a contact needle arrangement located on a needle head. The needle head having the contact needles is attached to what is known as a probe card, which forms an interface between a test system and the wafer via the contact needles of the needle head.

Wafer tests are typically carried out in the temperature range between- 60 °C and 400 °C, and in exceptional cases even at yet more extreme temperatures above and/or below the zero point.

In high-chip-performance test measurements, the problem occurs that the semiconductor wafer is locally heated, on the front face in the region of the current flow, above the temperature of the rear face in contact with the clamping device, since the heat dissipation is delayed as a result of the finite heat transfer resistance between the semiconductor wafer and the clamping device. Typically, at electrical powers of over 100 W, a local temperature difference of approximately 40 K occurs between the front face of the semiconductor wafer and the support face of the clamping device. This temperature difference disrupts the test measurement, which is in fact specifically intended to give the isothermal electrical properties of the circuits integrated into the semiconductor wafer. At the same time, at higher powers, the chips can be heated beyond a maximum permitted temperature, leading to the risk of an electrical failure.

EP 1 844 342 B1 discloses a device and a method for testing semiconductor wafers using a temperature-controllable clamping device, the method comprising the following steps: temperature-controlling the clamping device to a predetermined measurement temperature using an electrical heating device of a predetermined heating power and a cooling device, through which a fluid is passed for cooling, of a predetermined cooling power, applying the rear face of a semiconductor wafer to a support face of the temperature-controllable clamping device, placing a probe card on the front face of the semiconductor wafer, testing the temperature-controllable semiconductor wafer by imposing the test power of a test device on a chip region of the front face of the semiconductor wafer using probes of the placed probe card, and detecting a temperature increase, reflecting the test power, of the fluid during testing.

In this context, the heating power is greater than a predetermined test power, and the heating power is reduced by withdrawing the test power during testing at a substantially constant cooling power while taking account of the temperature increase of the fluid detected during testing. The temperature increase of the fluid is detected by taking account of the signals of an associated temperature detection device, which detects, during testing, the input temperature and output temperature of the fluid supplied to the clamping device from the cooling device for cooling.

This basically involves dissipating a high power, inputted at a point, through the clamping device (chuck). In this context, it is essential that the temperature regulation of the chuck behaves exactly identically at every position over the entire wafer (presently diameter 300 mm). The system functions well but has relatively slow thermal response properties.

EP 3 937 216 A1 discloses a method for setting the temperature of a substrate carrier, on which a substrate is placed, in a testing device for testing a test object device formed on the substrate, a substrate placement surface of the substrate carrier being subdivided into a plurality of regions and a heater being arranged in each of the plurality of regions. The method comprises the steps of: carrying out feedback control of the heater in a main region, corresponding to the test object device, out of the plurality of regions, in such a way that a temperature of the main region takes on a target temperature, controlling the heater in a sub-region next to the main region out of the plurality of regions, wherein when the heater is controlled in the sub-region, if no overshooting has occurred in the temperature of the main region, the heater in the sub-region is controlled in such a way that a temperature difference between the main region and the sub-region takes on a predetermined value, and wherein, if overshooting of the temperature has occurred in the main region, the heater of the sub-region is controlled in such a way that a temperature difference between the set target temperature and the temperature in the sub-region takes on the predetermined value.

US 2012/0396801 A1 discloses a test device comprising a test interface board comprising a plurality of socket interface boards, each socket interface board having a socket for receiving a DUT, a discrete active thermal interposer having thermal properties and serving to establish thermal contact with the DUT, a superstructure operable so as to include the discrete active thermal interposer, and an actuation mechanism operable so as to provide a contact force to bring the discrete active thermal interposer into contact with the DUT.

All known test devices fail to solve two problems with the wafer test:
1) How can the temperature in zones be controlled independently and rapidly in such a way that the chip temperature stays constant under dynamic load? It is only ever observed that the chuck itself remains thermally inert and cannot regulate the temperature by zone.
2) How can the temperature of the temperature sensor (chuck) be regulated in accordance with the temperature of the chips, and the thermal resistance between the upper chuck face and rear wafer face thus be eliminated?

Thus, the object of the present invention is to provide a device and a method for testing semiconductor wafers using a temperature-controllable clamping device which have improved thermal response properties.

To achieve this object, the present invention provides a device for testing semiconductor wafers using a temperature-controllable clamping device according to claim 1 and a method for testing semiconductor wafers using a temperature-controllable clamping device according to claim 17. A plate-shaped zone heating device according to claim 16 is also provided.

Preferred developments form the subject matter of the associated dependent claims.

The idea behind the present invention is to provide a temperature-controllable clamping device having a chuck device and a plate-shaped zone heating device, which can be applied to the chuck device and has a plurality of discrete heating zones. The heating zones are arranged in the form of a planar matrix below a support face of the zone heating device and are each enclosed by a lateral thermal insulation region. The lateral thermal insulation regions laterally inhibit heat propagation, but the heat propagation is maintained in a vertical direction. As a result, the excess heat due to testing can be dissipated more rapidly via the cooling of the chuck device, and the thermal response properties can be substantially improved. This in turn makes it possible to carry out test pulse sequences using a test power which is rapidly variable over time, without the measurement results being distorted by delayed heat dissipation.

In a preferred development, the temperature detection device is configured to detect a chip temperature increase, reflecting the test power, directly during testing and to pass the chip temperature increase to the temperature control device, the temperature control device being set up to reduce the heating power, at a constant cooling power, on the basis of the directly detected chip temperature increase during testing, so as to stabilise the measurement temperature.

In a further preferred development, the lateral thermal insulation regions have respective annular cavities in the plate-shaped zone heating device. This provides effective lateral thermal insulation.

In a further preferred embodiment, the annular cavities are arranged overlapping in the plate-shaped zone heating device. This makes it possible to save considerable space.

In a further preferred embodiment, the annular cavities in the plate-shaped zone heating device each have, on the rear face opposite the support face, an associated first vacuum terminal for evacuating the cavities. The effectiveness of the thermal shielding can thus be further increased.

In a further preferred embodiment, the annular cavities in the plate-shaped zone heating device are exposed at the support face. This likewise increases the effectiveness of the thermal shielding.

In a further preferred embodiment, the thermal insulation regions have a thermal insulation material embedded in the plate-shaped zone heating device. This increases the stability of the plate-shaped zone heating device.

In a further preferred embodiment, the plate-shaped zone heating device is formed from a ceramic, a glass ceramic, a glass or a plastics material. This makes manufacture simpler and more flexible. In a further preferred embodiment, the heating zones each have a heating resistor which can be controlled electrically via associated electrical terminals. In this way, precisely controllable zone heating can be formed.

In a further preferred embodiment, the temperature detection device has an associated temperature sensor device, which is integrated into the chips to be tested and which can be contacted via temperature probes of the probe card. This makes high-precision determination of the chip temperature increase possible in real time.

In a further preferred embodiment, the temperature detection device comprises an infrared thermometer arranged on the probe card. In this way, additional probes and an additional temperature sensor device in the chip to be tested can be omitted.

In a further preferred embodiment, the chuck device has a single cooling circuit for the coolant fluid. This simplifies manufacture.

In a further preferred embodiment, the chuck device has a plurality of cooling circuits, by way of which the individual heating zones can be cooled selectively individually by the coolant fluid. This further improves the response properties.

In a further preferred embodiment, a valve device controllable by the temperature control device is provided for selectively activating each individual cooling circuit.

In a further preferred embodiment, the chuck device has second vacuum suction grooves, via which the plate-shaped zone heating device can be applied to the chuck device. The plate-shaped zone heating device can thus be applied and removed again rapidly when required.

Embodiments of the invention are shown in the drawings and explained in greater detail in the following description.

In the drawings:

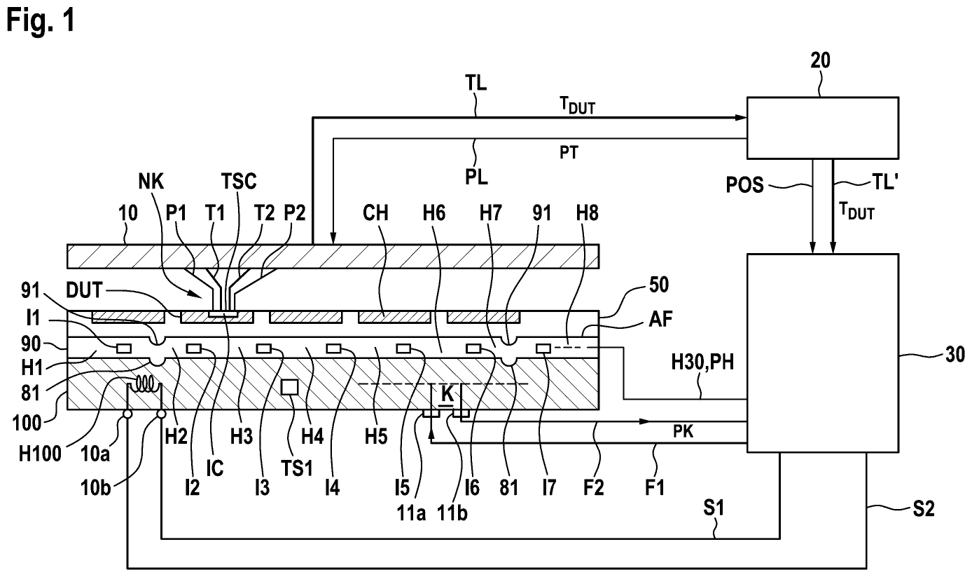

FIG. 1 is a schematic cross-sectional drawing of a device for testing semiconductor wafers in accordance with a first embodiment of the present invention,

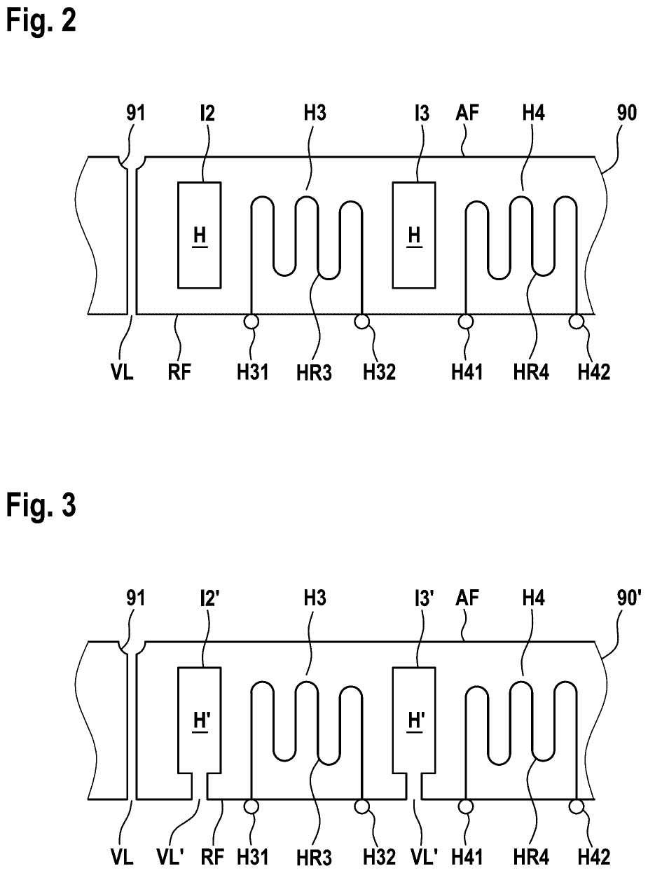

FIG. 2 is a partially schematic cross-sectional drawing of the zone heating device of the device for testing semiconductor wafers in accordance with the first embodiment of the present invention,

FIG. 3 is a partially schematic cross-sectional drawing of a modified zone heating device for a device for testing semiconductor wafers in accordance with a second embodiment of the present invention,

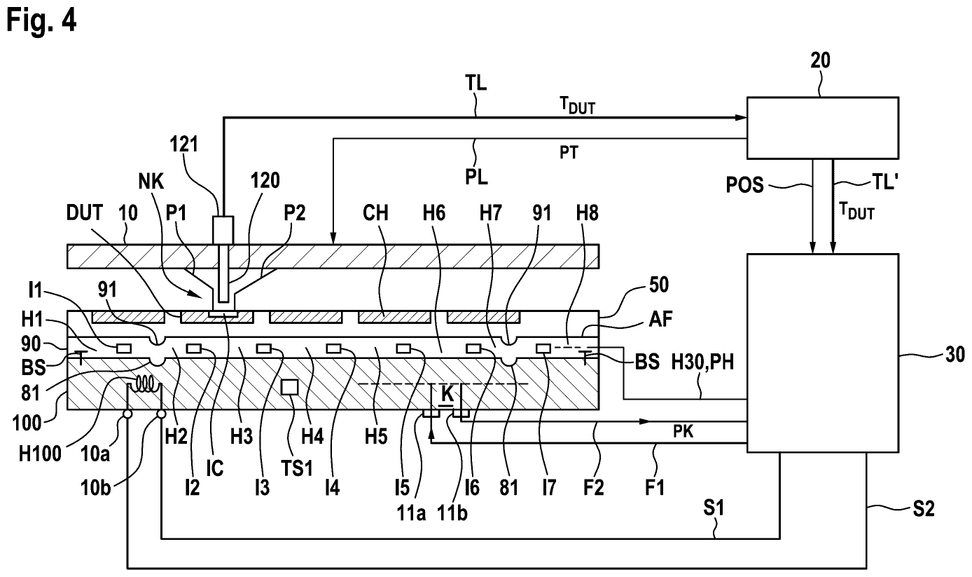

FIG. 4 is a schematic cross-sectional drawing of a device for testing semiconductor wafers in accordance with a third embodiment of the present invention,

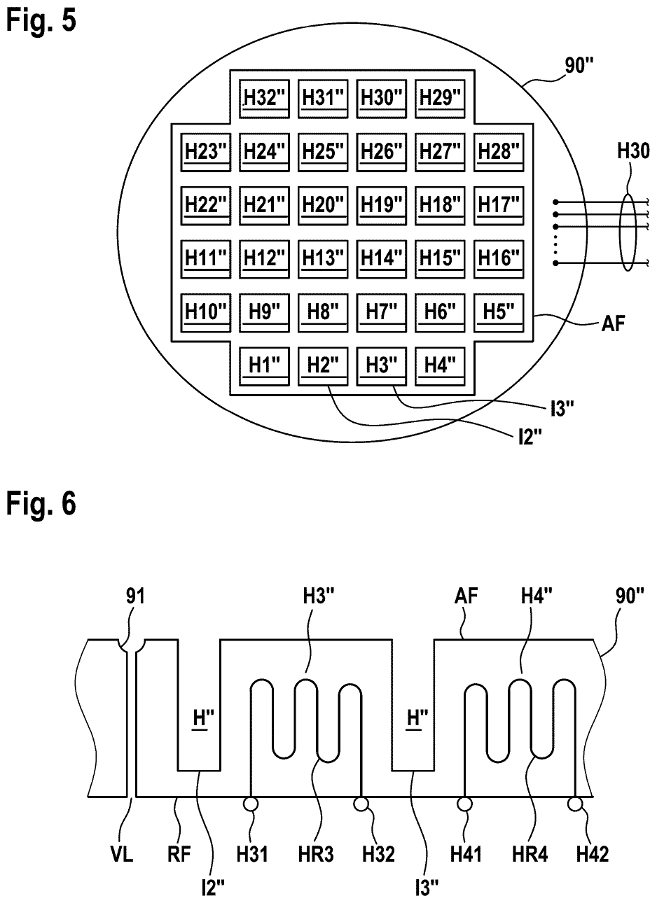

FIG. 5 is a planar plan view of a modified zone heating device for a device for testing semiconductor wafers in accordance with a fourth embodiment of the present invention,

FIG. 6 is a partially schematic cross-sectional drawing of the modified zone heating device of the device for testing semiconductor wafers in accordance with the fourth embodiment of the present invention,

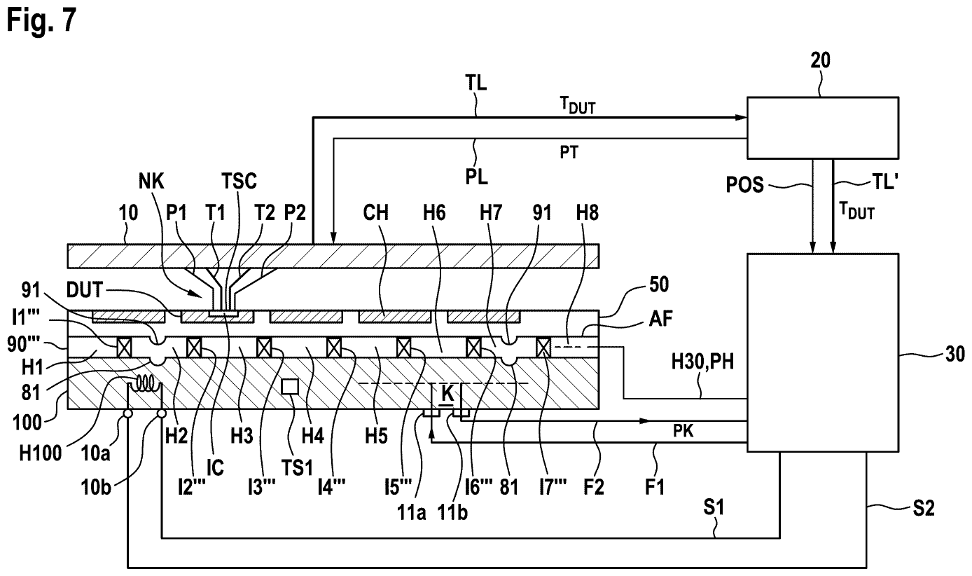

FIG. 7 is a schematic cross-sectional drawing of a device for testing semiconductor wafers in accordance with a fifth embodiment of the present invention, and

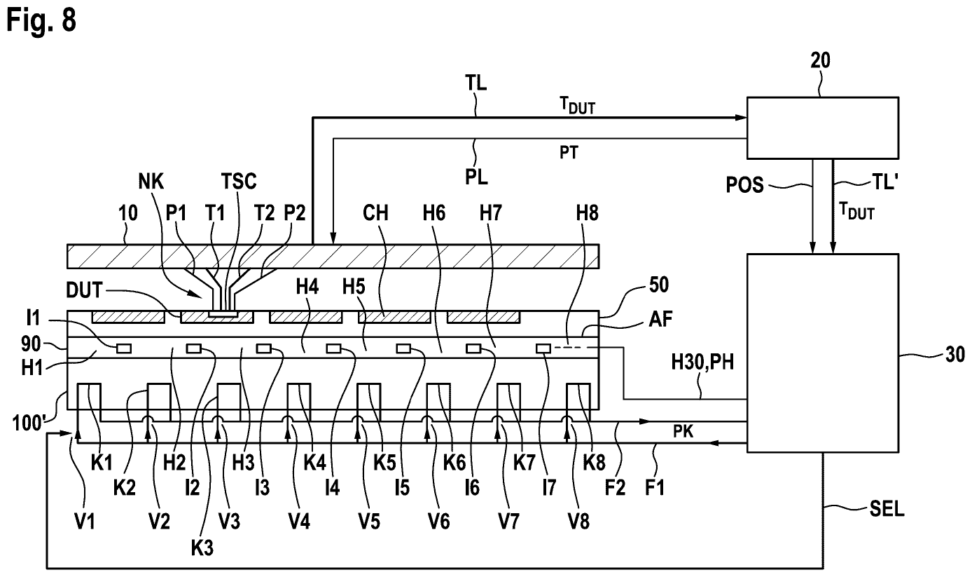

FIG. 8 is a schematic cross-sectional drawing of a device for testing semiconductor wafers in accordance with a sixth embodiment of the present invention.

In the drawings, like reference numerals denote like or functionally equivalent components. FIG. 1 is a schematic cross-sectional drawing of a device for testing semiconductor wafers in accordance with a first embodiment of the present invention.

In FIG. 1, reference numerals 90, 100 denote a temperature-controllable clamping device 90, 100 for a semiconductor wafer 50, which has a metal (e.g. Cu) chuck device 100 and a plate-shaped zone heating device 90 applicable or applied to the chuck device 100 and having a plurality of discrete heating zones H1-H8. By way of a drive mechanism (not shown), the temperature-controllable clamping device 90, 100 can be displaced in a vertical direction and within the contact plane of the semiconductor wafer 50, which plane is defined by the support face AF of the plate-shaped zone heating device 90. The support face AF has first vacuum suction grooves 91 for clamping the semiconductor wafer 50.

The chuck device 100 has second vacuum suction grooves 81, via which the plate-shaped zone heating device 90 can be clamped on the chuck device 100. The plate-shaped zone heating device can thus be applied and removed again rapidly when required. The chuck device 100 and the plate-shaped zone heating device 90 are usually configured round and have the same diameter, for example approximately 200 mm or 300 mm.

The heating zones H1-H8 (only shown in one dimension in FIG. 1; cf. FIG. 5) are arranged in the form of a planar matrix below the support face AF of the zone heating device 90 in the interior thereof and embedded in the material of the zone heating device 90. In the embodiment presently being described, the plate-shaped zone heating device 90 is formed from a ceramic, a glass ceramic, a glass or a plastics material.

The heating zones H1-H8 are each formed by a heating resistor, which can be electrically controlled individually via associated electrical terminals (cf. FIGS. 2 and 3). Their size is typically a few mm², in such a way that, depending on chip size, one or more chips CH of the semiconductor wafer 50 can be heated per heating zone.

In the present embodiments, the heating zones H1-H8 are square and are each enclosed by a lateral thermal insulation region I1-I7. The lateral insulation regions I1-I7 are peripheral and thus form insularly thermally insulated insulation regions I1-I7. The insulation regions I1-I7 are formed overlapping on the lateral faces of the heating zones H1-H8.

A programmable test control device 20 serves to test the temperature-controlled semiconductor wafer 50 clamped on the support face AF of the zone heating device 90 by imposing a predetermined electric test power PT on each chip DUT to be tested as an individual pulse or pulse sequence, on the front face of the semiconductor wafer 50 via probes P1, P2 on a needle head NK of a probe card 10. The electrical connection between the test control device 20 and the probe card extends via a line PL.

A temperature control device 30 is further provided, and is connected to the test device 20, the chuck device 100 and the zone heating device 90 and set up to set a predetermined measurement temperature at the chip DUT to be tested.

For this purpose, it controls the chuck device 90 to a predetermined cooling power PK using a coolant fluid. The coolant fluid is supplied to the chuck device 100 via an input line F1 and an input terminal 11a and discharged via an output line F2 and an output terminal 11b. In this embodiment, the chuck device 100 has a single cooling circuit K, indicated dashed in FIG. 1, for the coolant fluid. Optionally, the chuck device 100 may have a heating device H100, controllable by the temperature control device 30 via lines S1, S2 and corresponding terminals 10a, 10b, to stabilise the cooling.

One or more temperature sensors TS1, likewise electrically connected to the temperature control device 30 via lines (not shown), also serve this purpose.

Via a bus line H30, the temperature control device 30 may control an associated heating zone corresponding to the chip DUT to be tested to a predetermined heating power PH, the predetermined heating power PH being greater than the predetermined test power PT. For this purpose, it receives a position signal POS, which provides an allocation of the associated heating zone to be controlled to the chip DUT to be tested, from the test device 20 during testing.

A temperature detection device TSC in an integrated circuit IC of the chip DUT to be tested serves to detect a chip temperature increase, reflecting the test power PT, directly during testing. The temperature detection device TSC has an associated temperature sensor device TSC, which is integrated into the chips CH, DUT to be tested and which can be contacted via temperature probes T1, T2 of the probe card 10. This makes high-precision determination of the chip temperature increase possible in real time.

For this purpose, the chip temperature T_{OUT} is passed in real time to the test device 20 via a first temperature monitor line TL and from there to the temperature control device 30 via a second temperature monitor line TL′.

The temperature control device 30 is set up to reduce the heating power PH in the relevant heating zone—in this case H3—at a constant cooling power PK on the basis of the directly detected chip temperature increase during testing, so as to stabilise the measurement temperature.

The lateral thermal insulation regions—in this case 12, 13—laterally inhibit heat propagation, the heat propagation in a vertical direction to the chuck device 100 being maintained. As a result, the excess heat due to testing can be dissipated extremely rapidly via the cooling of the chuck device 100. This makes it possible to carry out test pulse sequences using a test power which is rapidly variable over time, without the measurement results being distorted by delayed heat dissipation.

FIG. 2 is a partially schematic cross-sectional drawing of the zone heating device of the device for testing semiconductor wafers in accordance with the first embodiment of the present invention.

As is shown in FIG. 2, the lateral thermal insulation regions I1-I7—of which 12 and 13 are shown here-have respective annular cavities H in the plate-shaped zone heating device 90, which ex-tend as close as possible towards the support face AF and opposite rear face RF.

The heating zones H1-H8—of which H3 and H4 are shown here—each have an associated heating resistor HR3, HR4 and are coiled in the heating zones H1-H8 so as to configure the heat power density as high as possible. Via associated electrical terminals H31, H32 and H41, H42 respectively, they can be controlled electrically by the temperature control device 30 via the bus line H30.

FIG. 3 is a partially schematic cross-sectional drawing of a modified zone heating device for a device for testing semiconductor wafers in accordance with a second embodiment of the present invention.

In the second embodiment, the annular cavities H′ in the plate-shaped zone heating device 90′ shown as thermal insulation regions 12′ and 13′ here-each have an associated first vacuum terminal VL′, for evacuating the cavities H′, on the rear face RF opposite the support face AF.

Otherwise, the second embodiment is configured analogously to the first embodiment.

FIG. 4 is a schematic cross-sectional drawing of a device for testing semiconductor wafers in accordance with a third embodiment of the present invention.

In the third embodiment, the temperature detection device 120, 121 is configured as an infrared thermometer 120, 121, which is arranged on the probe card 10 and which has an IR light guide 120 and an evaluation circuit 121, which is in turn connected to the first temperature monitor line TL. The probes T1, T2 are thus superfluous.

Otherwise, the third embodiment is configured analogously to the first embodiment.

FIG. 5 is a planar plan view and FIG. 6 is a partially schematic cross-sectional drawing of a modified zone heating device for a device for testing semiconductor wafers in accordance with a fourth embodiment of the present invention.

In the fourth embodiment, 32 square heating zones H1″-H32″ are provided, which are embedded under the support face AF. The terminals of the heating resistors are guided in the interior of the plate-shaped zone heating device 90″ up to the edge thereof, so as to be connected to the bus line H30 there.

Unlike in the previously described embodiments, the annular cavities H″ in the plate-shaped zone heating device 90″—shown as thermal insulation regions 12″ and 13″ here—which enclose the heating zones—in this case H3″ and H4″—are exposed at the support face AF.

Otherwise, the fourth embodiment is configured analogously to the first embodiment.

FIG. 7 is a schematic cross-sectional drawing of a device for testing semiconductor wafers in accordance with a fifth embodiment of the present invention

In the fifth embodiment, the thermal insulation regions I1′″-I7′″ have a thermal insulation material, for example glass fibres or the like, embedded in the plate-shaped zone heating device 90′″.

Otherwise, the fifth embodiment is configured analogously to the first embodiment.

FIG. 8 is a schematic cross-sectional drawing of a device for testing semiconductor wafers in accordance with a sixth embodiment of the present invention.

In the sixth embodiment, for clarity of the drawing, not all elements are depicted, but rather merely the substantially differences from the first embodiment.

In the sixth embodiment, the chuck device 100′ has a plurality of cooling circuits K1-K8, by way of which the individual heating zones H1-H8 can be cooled selectively individually by the coolant fluid. For this purpose, a valve device V1-V8, controllable by the temperature control device 30 via a control line SEL, is provided for selectively activating each individual cooling circuit K1-K8. The valve device V1-V8 has a valve for each cooling circuit on the line F1, said valve being opened when the relevant cooling circuit is activated.

Otherwise, the sixth embodiment is configured analogously to the first embodiment.

Although the present invention has been explained in the above by way of preferred embodiments, it is not limited thereto, but rather can be modified in numerous ways.

In particular, the shape, size and number of the thermal insulation regions and heating zones are merely exemplary and may be varied as desired.

1. Device for testing semiconductor wafers, comprising:
a temperature-controllable clamping device having a chuck device and a plate-shaped zone heating device, which can be applied to the chuck device and has a plurality of discrete heating zones;
the heating zones being arranged in the form of a planar matrix below a support face of the zone heating device and each being enclosed by a lateral thermal insulation region;
a test control device for testing a temperature-controlled semiconductor wafer clamped on the support face of the zone heating device by imposing a predetermined electric test power on each chip to be tested, on the front face of the semiconductor wafer via probes of a probe card;
a temperature control device which is connected to the test device the chuck device and the zone heating device and set up, for the purpose of setting a predetermined measurement temperature, to control the chuck device to a predetermined cooling power using a coolant fluid and to control an associated heating zone corresponding to the chip to be tested to a predetermined heating power the predetermined heating power being greater than the predetermined test power;
a temperature detection device for detecting a temperature increase during testing and passing the temperature increase to the temperature control device;
the temperature control device being set up to reduce the heating power at a constant cooling power on the basis of the directly detected chip temperature increase during testing, so as to stabilise the measurement temperature.

2. Device for testing semiconductor wafers according to claim 1, wherein
the temperature detection device is configured to detect a chip temperature increase, reflecting the test power directly during testing and to pass the chip temperature increase to the temperature control device and
the temperature control device is set up to reduce the heating power at a constant cooling power on the basis of the directly detected chip temperature increase during testing, so as to stabilise the measurement temperature.

3. Device for testing semiconductor wafers according to claim 1, wherein the lateral thermal insulation regions have respective annular cavities in the plate-shaped zone heating device.

4. Device for testing semiconductor wafers according to claim 3, wherein the annular cavities are arranged overlapping in the plate-shaped zone heating device.

5. Device for testing semiconductor wafers according to claim 3, wherein the annular cavities in the plate-shaped zone heating device each have, on the rear face opposite the support face an associated first vacuum terminal for evacuating the cavities.

6. Device for testing semiconductor wafers according to claim 3, wherein the annular cavities in the plate-shaped zone heating device are exposed at the support face.

7. Device for testing semiconductor wafers according to claim 3, wherein the thermal insulation regions have a thermal insulation material embedded in the plate-shaped zone heating device.

8. Device for testing semiconductor wafers according to claim 1, wherein the plate-shaped zone heating device is formed from a ceramic, a glass ceramic, a glass or a plastics material.

9. Device for testing semiconductor wafers according to claim 1, wherein the heating zones each have a heating resistor which can be controlled electrically via associated electrical terminals.

10. Device for testing semiconductor wafers according to claim 1, wherein the temperature detection device has an associated temperature sensor device which is integrated into the chips to be tested and which can be contacted via temperature probes of the probe card.

11. Device for testing semiconductor wafers according to claim 1, wherein the temperature detection device comprises an infrared thermometer arranged on the probe card.

12. Device for testing semiconductor wafers according to claim 1, wherein the chuck device has a single cooling circuit for the coolant fluid.

13. Device for testing semiconductor wafers according to claim 1, wherein the chuck device has a plurality of cooling circuits, by way of which the individual heating zones can be cooled selectively individually by the coolant fluid.

14. Device for testing semiconductor wafers according to claim 13, wherein a valve device controllable by the temperature control device is provided for selectively activating each individual cooling circuit.

15. Device for testing semiconductor wafers according to claim 1, wherein the chuck device has second vacuum suction grooves, via which the plate-shaped zone heating device can be applied to the chuck device.

16. Plate-shaped zone heating device for heating semiconductor wafers using a plurality of discrete heating zones wherein the heating zones can be heated selectively and are arranged in the form of a planar matrix below a support face of the zone heating device for a semiconductor wafer and are each enclosed by a lateral thermal insulation region said device being applicable to a chuck device in particular for use in a device for testing semiconductor wafers according to claim 1.

17. Method for testing semiconductor wafers using a temperature-controllable clamping device, comprising the steps of:
providing a temperature-controllable clamping device having a chuck device and a plate-shaped zone heating device, which can be applied to the chuck device and has a plurality of discrete heating zones; the heating zones being arranged in the form of a planar matrix below a support face of the zone heating device and each being enclosed by a lateral thermal insulation region;
testing a temperature-controlled semiconductor wafer clamped on the support face of the zone heating device by imposing a predetermined electric test power on each chip to be tested, on the front face of the semiconductor wafer via probes of a probe card;
for the purpose of setting a predetermined measurement temperature, controlling the chuck device to a predetermined cooling power using a coolant fluid and controlling an associated heating zone corresponding to the chip to be tested to a predetermined heating power the predetermined heating power being greater than the predetermined test power;
detecting a temperature increase during testing; and
reducing the heating power at a constant cooling power on the basis of the detected temperature increase during testing, so as to stabilise the measurement temperature.

18. Device for testing semiconductor wafers according to claim 17, wherein
a chip temperature increase, reflecting the test power is detected directly during testing; and
the heating power is reduced, at a constant cooling power on the basis of the directly detected chip temperature increase during testing, so as to stabilise the measurement temperature.
